(19) United States
(12) Patent Application Publication
(10) Pub. No.: US 2026/0153575 A1
(43) Pub. Date: Jun. 4, 2026

(54) Magnetic Permeability Measuring Method

(71) Applicant: TOHOKU UNIVERSITY, Sendai-shi (JP)

(72) Inventors: Shin Yabukami, Sendai-shi (JP); Kazuhiko Okita, Sendai-shi (JP)

(21) Appl. No.: 19/460,448

(22) Filed: Jan. 27, 2026

Related U.S. Application Data
(63) Continuation of application No. PCT/JP2023/027961, filed on Jul. 31, 2023.

(51) Int. Cl. G01R 33/12; G01R 33/00

(52) U.S. Cl. CPC G01R 33/1223; G01R 33/0029

(57) ABSTRACT

Provided herein is a magnetic permeability measuring method including measuring a measured permeability coefficient of the magnetic material using a measuring probe; setting an analysis model corresponding to a measurement condition, and calculating, using finite element analysis, a calculated permeability coefficient of the magnetic material in the analysis model and the magnetic permeability of the magnetic material corresponding to the calculated permeability coefficient; acquiring a first set including a plurality of pairs of real-parts and imaginary-parts of the magnetic permeability corresponding to a real-part of the calculated permeability coefficient that matches a real-part of the measured permeability coefficient; acquiring a second set including a plurality of pairs of real-parts and imaginary-parts of the magnetic permeability corresponding to an imaginary-part of the calculated permeability coefficient that matches an imaginary-part of the measured permeability coefficient; and determining the magnetic permeability whose real-part and imaginary-part match in the first and second sets.

### CROSS-REFERENCE TO RELATED APPLICATION

This application is a bypass continuation of International Patent Application No. PCT/JP2023/027961 filed Jul. 31, 2023, the disclosure of which is hereby incorporated by reference in its entirety.

### BACKGROUND OF THE INVENTION

### Field of the Invention

The present invention relates to a magnetic permeability measuring method for measuring a magnetic permeability of a magnetic material.

### Description of Related Art

Currently, high-frequency applications using a GHz band such as mobile phones and wireless communication have become popular. There is a strong demand for high-frequency magnetic materials that can be used to further miniaturize and integrate components of these high-frequency applications, and in particular, a magnetic film having a high magnetic permeability is essential for a magnetic material used in a circuit. Simultaneously, establishment of a high-frequency magnetic permeability evaluating method is essential.

### SUMMARY OF THE INVENTION

Inventors of the present invention have developed a magnetic permeability measuring device that does not require laborious processing on samples. Each of JP2010-060367A, JP2012-032165A, JP2015-172497A, and JP2016-053569A discloses a probe for measuring a magnetic permeability of a magnetic material, particularly a film-like magnetic material, and a magnetic permeability measuring device, which have been developed by the inventors. Each of the probes has a structure in which a dielectric layer is sandwiched between a strip conductor to which a high-frequency carrier signal is supplied and a ground conductor, and the magnetic material to be measured is brought into contact with the conductors to measure a permeability coefficient S₂₁ of the magnetic material to be measured, so that the magnetic permeability of the magnetic material is obtained.

The obtained magnetic permeability is a complex relative magnetic permeability μᵣ represented by the following equation (1), in which μᵣ′ is a real part of the complex relative magnetic permeability μᵣ, and μᵣ″ is an imaginary part of the complex relative magnetic permeability μᵣ.

$$\begin{matrix}[ Math . 1 ] & \\ {μ}_{r} = {μ}_{r}^{′} - j {μ}_{r}^{″} & ( 1 )\end{matrix}$$

The real part μᵣ′ of the complex magnetic permeability μᵣ corresponds to an inductance component L of the magnetic material, and the imaginary part μᵣ″ of the complex magnetic permeability μᵣ corresponds to a loss (resistance component) of the magnetic material.

On the other hand, high frequency magnetic materials such as ferrites used in high frequency bands are becoming thicker. For example, for thick magnetic materials with a thickness of 10 μm to 50 μm, in the method of bringing the probe having a structure in which the dielectric layer is sandwiched between the strip conductor and the ground conductor into contact with the magnetic material to be measured, to measure the permeability coefficient S₂₁ of the magnetic material to be measured, measurement errors may occur due to demagnetizing fields.

When a thick magnetic material is excited, magnetization moves in a thickness direction within the magnetic material, generating a demagnetizing field, which does not occur in a thin-film magnetic material of, for example, 10 μm or less. When a film-like magnetic material is locally excited by a linear strip conductor, a demagnetizing field is generated outside the locally generated magnetic field of the magnetic material, and therefore, the influence of the demagnetizing field is to cancel out the magnetic flux of the excited magnetic field, which causes an error in the actual magnetic permeability of the magnetic material to be measured. More specifically, there may be a case where a resonance frequency in the imaginary part μᵣ″ of the complex relative magnetic permeability μᵣ in the above Equation (1) is deviated, and the magnetic permeability cannot be measured with high accuracy.

FIG. 14 includes graphs showing measurement examples in which an error occurs in the imaginary part of the magnetic permeability due to the influence of the demagnetizing field. FIG. 14 shows a measurement value obtained using a probe equipped with a microstrip line of an elongated conductor and a measurement value obtained using the Nicolson-Ross-Weir (NRW) method, which is a standard magnetic permeability measuring method that is not influenced by the demagnetizing field, in which A of FIG. 14 shows values of the imaginary part μᵣ″ of the complex relative magnetic permeability μᵣ, and B of FIG. 14 shows values of the real part μᵣ′ of the complex relative magnetic permeability μᵣ. The magnetic material to be measured is a NiZn ferrite sheet (3 mm×3 mm×thickness 100 μm), and as shown in A of FIG. 14, on the basis of the measurement value according to the NRW method, the resonance frequency in the imaginary part μᵣ″ of the complex relative magnetic permeability μᵣ is deviated to the high frequency side by 7 GHz, and a large error occurs in the measurement value. Note that the measurement values of the real part μᵣ′ of the complex relative magnetic permeability μᵣ shown in B of FIG. 14 appear to be roughly in line with the measurement value obtained by the NRW method, but the resonance frequency should have moved to the high frequency side in the same way, and observation may be difficult due to noise.

Magnetic permeability evaluation of the magnetic material, which is a sample to be measured, is often performed using a standard measurement method, such as the Nicolson-Ross-Weir (NRW) method, but the sample is required to be precisely machined into a toroidal shape and to be precisely positioned in a coaxial tube, which is technically difficult and labor-consuming.

On the other hand, when measuring the magnetic permeability by setting the magnetic material close to the strip conductor, when measuring a thick sheet-like magnetic material that has a large area as compared with a width of the strip conductor, the ferromagnetic resonance frequency shifts and the magnetic permeability fluctuates due to the movements in magnetization that occur in the thickness direction of the magnetic material due to the large thickness and the influence of the demagnetizing field caused by local application of a magnetic field, making it difficult to accurately measure the inherent magnetic permeability of the material.

An object of the invention is to provide a magnetic permeability measuring method that can measure, with high accuracy, a magnetic permeability of a magnetic material, particularly a thick sheet-like magnetic material having a relatively large thickness.

In order to achieve the above object, a magnetic permeability measuring method for measuring a magnetic permeability of a magnetic material according to the invention includes: a step of measuring a measured permeability coefficient of the magnetic material using a measuring probe; a step of setting an analysis model corresponding to a measurement condition in the measuring step, and calculating, using finite element analysis, a calculated permeability coefficient of the magnetic material in the analysis model and the magnetic permeability of the magnetic material corresponding to the calculated permeability coefficient; a step of acquiring a first set including a plurality of pairs of real parts and imaginary parts of the magnetic permeability corresponding to a real part of the calculated permeability coefficient that matches a real part of the measured permeability coefficient; a step of acquiring a second set including a plurality of pairs of real parts and imaginary parts of the magnetic permeability corresponding to an imaginary part of the calculated permeability coefficient that matches an imaginary part of the measured permeability coefficient; and a step of determining the magnetic permeability whose real part and imaginary part match in the first set and the second set.

According to the invention, the magnetic permeability of particularly a thick sheet-like magnetic material can be measured easily and with high accuracy.

### BRIEF DESCRIPTION OF THE DRAWINGS

FIG. 1 is a diagram illustrating a schematic configuration example of a magnetic permeability measuring device according to an embodiment of the invention.

FIGS. 2A and 2B are diagrams illustrating a configuration example of a probe 10.

FIG. 3 is a diagram illustrating an analysis model based on electromagnetic field analysis software of an arithmetic processing program.

FIG. 4 is a flowchart showing a magnetic permeability measuring method according to the embodiment of the invention.

FIG. 5 is a diagram illustrating optimization processing by the electromagnetic field analysis software using a finite element method.

FIG. 6 is a diagram illustrating the optimization processing by the electromagnetic field analysis software using the finite element method.

FIG. 7 is a diagram illustrating the optimization processing by the electromagnetic field analysis software using the finite element method.

FIGS. 8A and 8B are diagrams illustrating a first measurement result example of the magnetic permeability measuring method according to the embodiment.

FIG. 9 is a diagram illustrating the first measurement result example of the magnetic permeability measuring method according to the embodiment.

FIGS. 10A and 10B are diagrams illustrating a second measurement result example of the magnetic permeability measuring method according to the embodiment.

FIG. 11 is a diagram illustrating the second measurement result example of the magnetic permeability measuring method according to the embodiment.

FIG. 12 is a flowchart showing another processing procedure of the magnetic permeability measuring method according to the embodiment of the invention.

FIG. 13 is an example of a graph showing a part of real parts Re{S₂₁mea} of a measured permeability coefficient S₂₁mea before approximation processing and an approximated measured permeability coefficient S₂₁mea.

FIGS. 14A and 14B include graphs showing measurement examples in which an error occurs in an imaginary part of a magnetic permeability due to influence of a demagnetizing field.

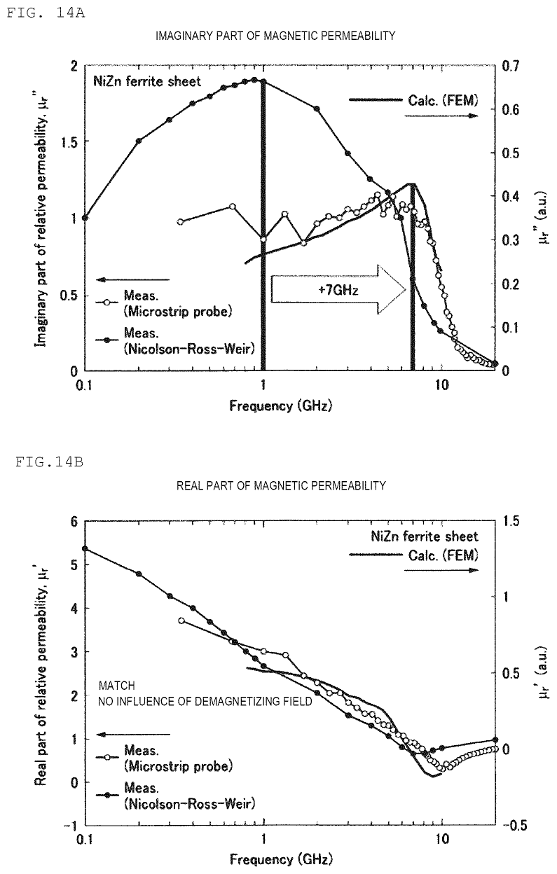

### DESCRIPTION OF THE INVENTION

Hereinafter, an embodiment of the invention will be described with reference to the drawings. However, the embodiment does not limit the technical scope of the invention.

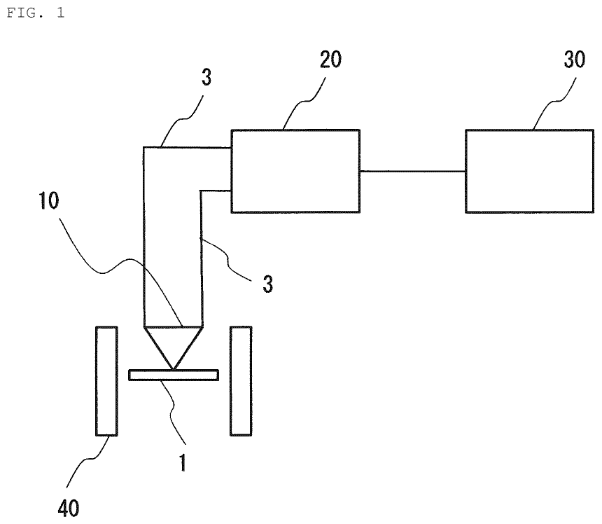

FIG. 1 is a diagram illustrating a schematic configuration example of a magnetic permeability measuring device according to the embodiment of the invention. The magnetic permeability measuring device according to the embodiment of the invention includes a probe 10, a network analyzer (signal measuring device) 20, and an arithmetic processing device (for example, a computer device such as a personal computer) 30 (processing unit) for executing numerical value analysis processing.

A magnetic material 1 to be measured is a thick sheet-like magnetic material, for example, which is thicker than approximately 10 μm to 50 μm. The probe 10 is set in a manner of being in contact or close to the magnetic material 1, and is connected to the network analyzer 20 via a non-magnetic coaxial cable 3. A current signal is supplied by the network analyzer 20, and a permeability coefficient S₂₁ of the magnetic material 1 to be measured is measured, and signal data thereof is input to the arithmetic processing device (computer device) 30, and a complex magnetic permeability of the magnetic material is obtained by predetermined numerical value analysis processing (including optimization processing described below). In order to magnetically saturate the magnetic material 1, for example, a magnet (magnetic field application unit) made of an electromagnet 40 is used.

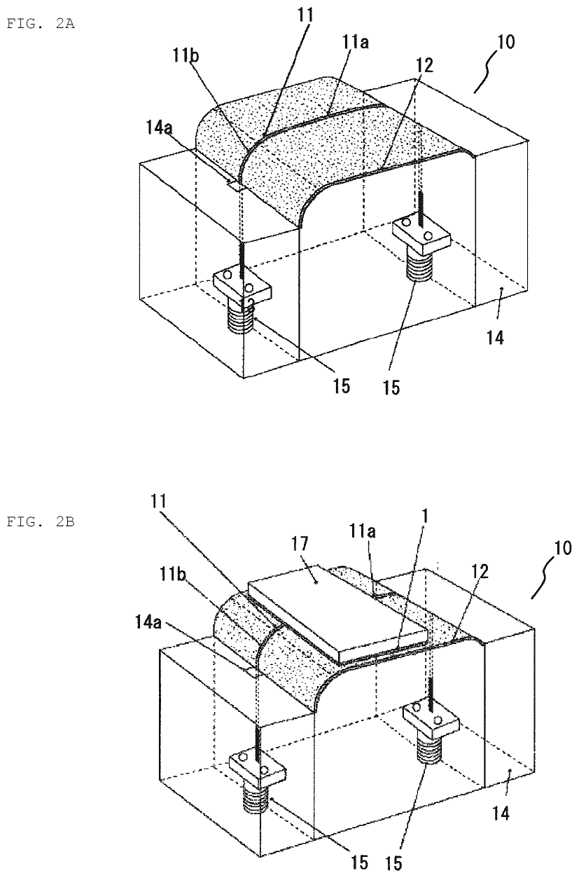

FIG. 2 is a diagram illustrating a configuration example of the probe 10, in which A of FIG. 2 illustrates a form of the probe 10 and B of FIG. 2 illustrates a state in which a sample is set on the probe 10. As illustrated in A of FIG. 2, the probe 10 is provided with a signal transmission line including a belt-like strip conductor formed on a front face of a dielectric substrate and a ground conductor formed on the front face or a back face of the dielectric substrate, and specifically including a microstrip conductor 11 (width=0.4 mm), a dielectric flexible substrate (sheet) 12 (for example, ROGERS duroid 5880, relative dielectric constant=2.2, thickness=0.127 mm), a ground conductor 14, and a pair of connectors 15 connected to both ends of the microstrip conductor 11. The probe 10 is provided with a microstrip line formed by sandwiching the dielectric flexible substrate 12 between the microstrip conductor 11 and the ground conductor 14.

Each of the connectors 15 is connected to a signal cable 3 (FIG. 1). The microstrip conductor 11 and the flexible substrate 12 are integrally fixed together by a chemical treatment or a thermal treatment. In the first configuration example, the flexible substrate 12 is pressed against the ground conductor 14 having a planar structure and a curved structure. Although the inside of the ground conductor 14 is illustrated as being transparent for convenience of description, the ground conductor 14 is actually made of a metal material such as copper. The microstrip conductor 11 is formed by etching. The microstrip conductor 11 includes a central linear portion 11a and curved portions 11b on both sides of the linear portion 11a. The ends of the microstrip conductor 11 are electrically connected to the connectors 15, respectively. The microstrip conductor 11 has a characteristic impedance matching of 50Ω for both the linear portion 11a and the curved portions 11b. The configuration in which the dielectric flexible substrate 12 is sandwiched between the microstrip conductor 11 and the ground conductor 14 forms a microstrip line.

As illustrated in B of FIG. 2, the magnetic material 1 to be measured is prepared by being adhered to a planar substrate 17, and is set with a pressure (not illustrated) applied from above so as to be close to or in contact with the microstrip conductor 11.

The microstrip conductor 11 extends into the ground conductor 14 through an opening 14a provided in the ground conductor 14 and is connected to the connector 15 on the opposite face side. For example, when a large-diameter magnetic material 1 and the substrate 17 are set close to each other, measurement can be performed without colliding with the connectors 15 or the signal cable 3 (FIG. 1) connected thereto. Note that although FIG. 2 illustrates the connectors 15 as being inside the ground conductor 14, the connectors 15 are exposed from the ground conductor 14 and connected to the signal cable 3.

The microstrip conductor 11 and the magnetic material 1 may be directly in contact with each other, or a predetermined gap may be provided between the microstrip conductor 11 and the magnetic material 1 for measurement. The gap can be formed by, for example, setting a flexible substrate between the microstrip conductor 11 and the magnetic material 1, or applying an insulating material such as a resist to a thickness of several microns. Alternatively, a gap forming jig is provided around the probe 10 so as to set the gap to a predetermined amount, and the microstrip conductor 11 is set close to the magnetic material 1 for measurement.

The probe 10 is not limited to the configuration of the microstrip line illustrated in FIG. 2, but may be other transmission lines such as a coplanar line.

The arithmetic processing device 30 in the magnetic permeability measuring device of FIG. 1 functions as a magnetic permeability calculation unit for obtaining a high frequency magnetic permeability of the magnetic material 1 by arithmetic processing, and executes an arithmetic processing program for calculating the magnetic permeability. The arithmetic processing program is a computer program that executes magnetic permeability measurement processing by calculation, which will be described below. The arithmetic processing program includes general-purpose electromagnetic field analysis software that executes finite element analysis, and as the electromagnetic field analysis software, for example, HFSS by Ansys, Inc can be used.

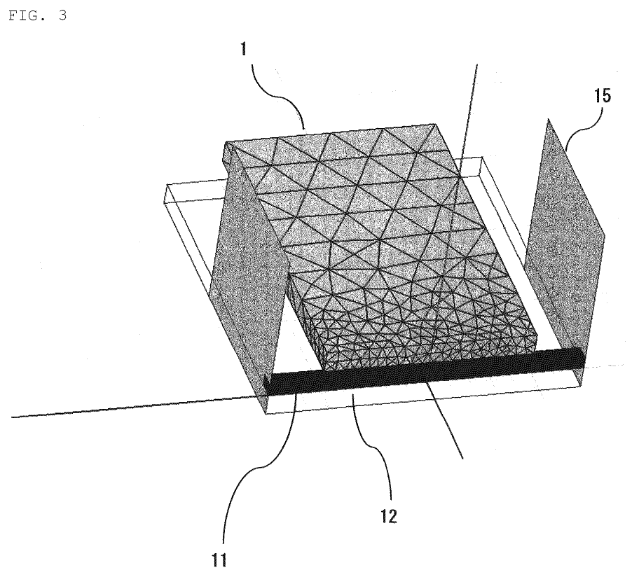

FIG. 3 is a diagram illustrating an analysis model based on the electromagnetic field analysis software of the arithmetic processing program. Measurement conditions of the magnetic permeability measuring device including the configuration of the probe 10 illustrated in FIG. 2 are modeled, and the permeability coefficient S₂₁ of the magnetic material 1 to be measured and a magnetic permeability (complex relative magnetic permeability) corresponding thereto are calculated by electromagnetic field analysis simulation operation, as will be described below. More specifically, the permeability coefficient S₂₁ when the magnetic permeability of the magnetic material is changed is obtained by arithmetic operation. The probe 10 in FIG. 2 has a bilaterally symmetrical structure with the microstrip conductor 11 at the center, and therefore, in FIG. 3, a half model of one side thereof is illustrated.

A magnetic permeability measuring procedure of the magnetic permeability measuring device according to the above embodiment will be described below.

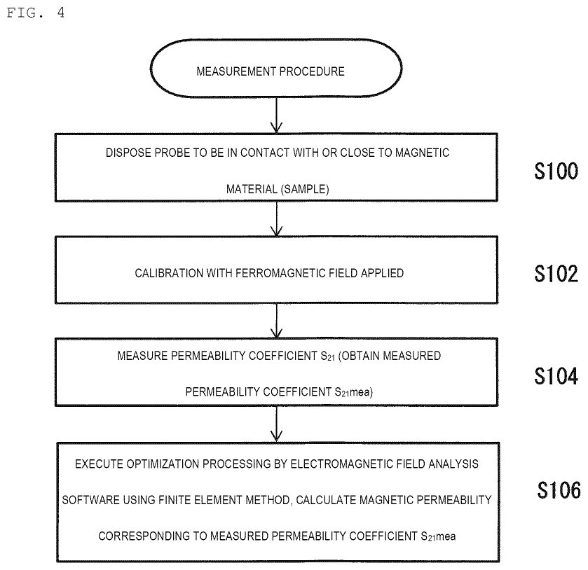

FIG. 4 is a flowchart showing a processing procedure of the magnetic permeability measuring method according to the embodiment of the invention. The probe 10 is brought into contact with or close to the magnetic material 1 to be measured (S100). Then, the magnetic material 1 is placed in a pole gap of the electromagnet 40, a strong DC magnetic field (for example, approximately 20 kOe) is applied thereto, the magnetic material 1 is saturated, and calibration is performed by the network analyzer 20 (S102). In this way, electrical lengths of the probe 10 and the coaxial cable 3, a DC impedance of the magnetic material 1, a non-magnetic signal, and the like are removed. Thereafter, the DC magnetic field is removed to measure the permeability coefficient S₂₁ contributed by the magnetic material 1 (S104).

Note that in the following description, the permeability coefficient S₂₁ measured in S104 is referred to as a measured permeability coefficient S₂₁mea, and the permeability coefficient S₂₁ calculated by the simulation operation of the electromagnetic field analysis software based on the analysis model of FIG. 3 is referred to as a calculated permeability coefficient S₂₁cal. Note that the permeability coefficient S₂₁ is a complex number represented by the following equation (2), Re{S₂₁} is a real part of the complex permeability coefficient S₂₁, and Im{S₂₁} is an imaginary part of the complex permeability coefficient S₂₁.

$${S}_{21} = Re \{ {S}_{21} \} + j Im \{ {S}_{21} \} \qquad ( 2 )$$

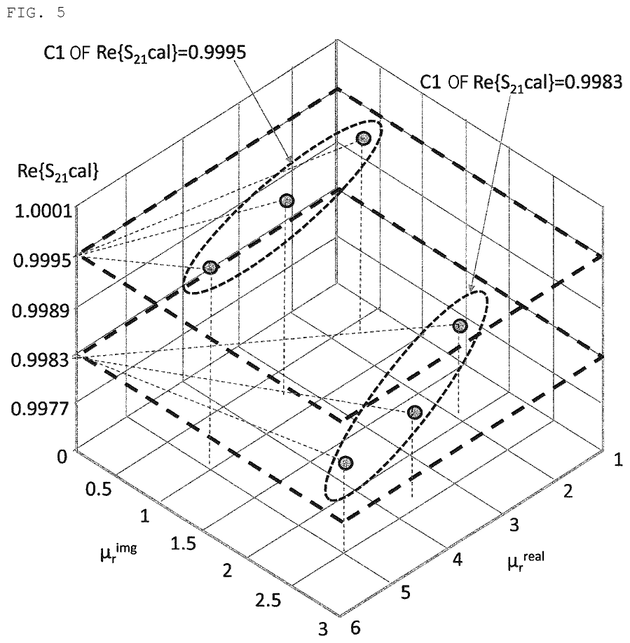

The measured permeability coefficient S₂₁mea obtained in S104 is subjected to the optimization processing by the electromagnetic field analysis software using the finite element method, so that the magnetic permeability corresponding to the measured permeability coefficient S₂₁mea is calculated (S106). The optimization processing by the electromagnetic field analysis software using the finite element method will be described with reference to FIGS. 5, 6, and 7.

FIGS. 5, 6, and 7 are diagrams illustrating the optimization processing by the electromagnetic field analysis software using the finite element method. The optimization processing (S106) by the electromagnetic field analysis software using the finite element method includes the following steps based on a relation between the calculated permeability coefficient S₂₁cal calculated in advance by the electromagnetic field analysis software using the finite element method and the (complex) magnetic permeability μ corresponding thereto:

S106-1) acquiring a plurality of pairs C1 of real parts μ^{real} and imaginary parts μ^{imag} of the magnetic permeability μ corresponding to a real part Re{S₂₁cal} of the calculated permeability coefficient S₂₁cal that matches a real part Re{S₂₁mea} of the measured permeability coefficient S₂₁mea;

S106-2) acquiring a plurality of pairs C2 of real parts μᵣ^{real} and imaginary parts μᵣ^{imag} of a relative magnetic permeability μᵣ corresponding to an imaginary part Im{S₂₁cal} of the calculated permeability coefficient S₂₁cal that matches an imaginary part Im{S₂₁mea} of the measured permeability coefficient S₂₁mea; and

S106-3) obtaining one relative magnetic permeability μᵣ whose real part μᵣ^{real} and imaginary part μᵣ^{imag} match in the plurality of pairs C1 and C2 and determining the obtained relative magnetic permeability μᵣ as the relative magnetic permeability μᵣ corresponding to the measured permeability coefficient S₂₁mea.

Specifically, FIG. 5 illustrates the step of S106-1, and illustrates values of the real part Re{S₂₁cal} of the calculated permeability coefficient S₂₁cal calculated by changing the magnetic permeability μ in the analysis model of FIG. 3. The calculated permeability coefficient S₂₁cal corresponding to the magnetic permeability μᵣ constituted by a plurality of pairs (sets) of set values (for example, all pairs of μᵣ^{real}=1 and μᵣ^{imag}=0, μᵣ^{real}=1 and μᵣ^{imag}=0.5, μᵣ^{real}=1 and μᵣ^{imag}=1, . . . , μᵣ^{real}=1 and μᵣ^{imag}=3, μᵣ^{real}=2 and μᵣ^{imag}=0, μᵣ^{real}=2 and μᵣ^{imag}=0.5, . . . , μᵣ^{real}=2 and μᵣ^{imag}=3, . . . , μᵣ^{real}=3 and μᵣ^{imag}=5, . . . , μᵣ^{real}=3 and μᵣ^{imag}=6, . . . ) within predetermined numerical ranges for the real part μᵣ^{real} and the imaginary part μᵣ^{imag} of the relative magnetic permeability Ur is calculated, and the values of the real part Re{S₂₁cal} are plotted. In FIG. 5, only a part of the calculated real parts Re{S₂₁cal} are illustrated for understanding of the drawing.

In the calculation of the calculated permeability coefficient S₂₁cal, there are a plurality of pairs (sets) of the real part μ^{real} and the imaginary part μ^{imag} of the magnetic permeability μ in which the real part Re{S₂₁cal} of the calculated permeability coefficient S₂₁cal becomes a predetermined value, and FIG. 5 illustrates, as an example, a plurality of pairs C1 of the real part μᵣ^{real} and the imaginary part μᵣ^{imag} of the relative magnetic permeability μᵣ in which the real part Re{S₂₁cal}=0.9995 and a plurality of pairs C1 of the real part μᵣ^{real} and the imaginary part μᵣ^{imag} of the relative magnetic permeability μᵣ in which the real part Re{S₂₁cal}=0.9983. Note that the number of the plurality of pairs C1 is not limited to three as illustrated in FIG. 5. In the step of S106-1, the plurality of pairs C1 of the real part μᵣ^{real} and the imaginary part μᵣ^{imag} of the relative magnetic permeability μᵣ corresponding to the real part Re{S₂₁cal} of the calculated permeability coefficient S₂₁cal that matches the real part Re{S₂₁mea} of the measured permeability coefficient S₂₁mea are obtained.

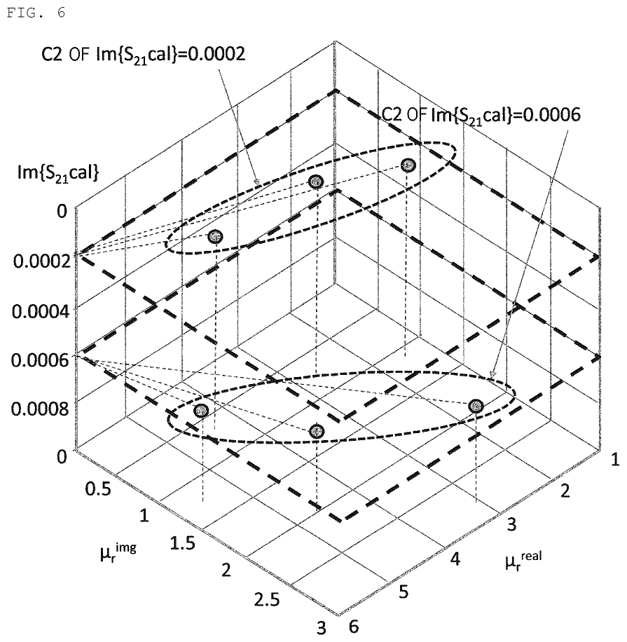

Similarly, FIG. 6 illustrates the step of S106-2, and illustrates values of the imaginary part Im{S₂₁cal} of the calculated permeability coefficient S₂₁cal calculated by changing the magnetic permeability μᵣ in the analysis model of FIG. 3. Similarly to the step of S106-1 described above, the calculated permeability coefficient S₂₁cal corresponding to the relative magnetic permeability μᵣ constituted by a plurality of pairs (sets) of set values (for example, all pairs of μᵣ^{real}=1 and μᵣ^{imag}=0, μᵣ^{real}=1 and μᵣ^{imag}=0.5, μᵣ^{real}=1 and μᵣ^{imag}=1, . . . , μᵣ^{real}=1 and μᵣ^{imag}=3, μᵣ^{real}=2 and μᵣ^{imag}=0, μᵣ^{real}=2 and μᵣ^{imag}=0.5, . . . , μᵣ^{real}=2 and μᵣ^{imag}=3, . . . , μᵣ^{real}=3 and μᵣ^{imag}=5, . . . , μᵣ^{real}=3 and μᵣ^{imag}=6, . . . ) within predetermined numerical ranges for the real part μᵣ^{real} and the imaginary part u imag of the relative magnetic permeability μᵣ is calculated, and the values of the imaginary part Im{S₂₁cal} are plotted. In FIG. 6, only a part of the calculated imaginary parts Im{S₂₁cal} are illustrated for understanding of the drawing.

In the calculation of the calculated permeability coefficient S₂₁cal, there are a plurality of pairs (sets) of the real part μᵣ^{real} and the imaginary part μᵣ^{imag} of the relative magnetic permeability μᵣ in which the imaginary part Im{S₂₁cal} of the calculated permeability coefficient S₂₁cal becomes a predetermined value, and FIG. 6 illustrates, as an example, a plurality of pairs C2 of the real part μᵣ^{real} and the imaginary part μᵣ^{imag} of the relative magnetic permeability μᵣ in which the imaginary part Im{S₂₁cal}=0.0002 and a plurality of pairs C2 of the real part μᵣ^{real} and the imaginary part μᵣ^{imag} of the relative magnetic permeability μᵣ in which the imaginary part Im{S₂₁cal}=0.0006. Note that the number of the plurality of pairs C2 is not limited to three as illustrated in FIG. 6. In the step of S106-2, the plurality of pairs C2 of the real part u real and the imaginary part μᵣ^{imag} of the relative magnetic permeability μᵣ corresponding to the imaginary part Im{S₂₁cal} of the calculated permeability coefficient S₂₁cal that matches the imaginary part Im{S₂₁mea} of the measured permeability coefficient S₂₁mea are obtained.

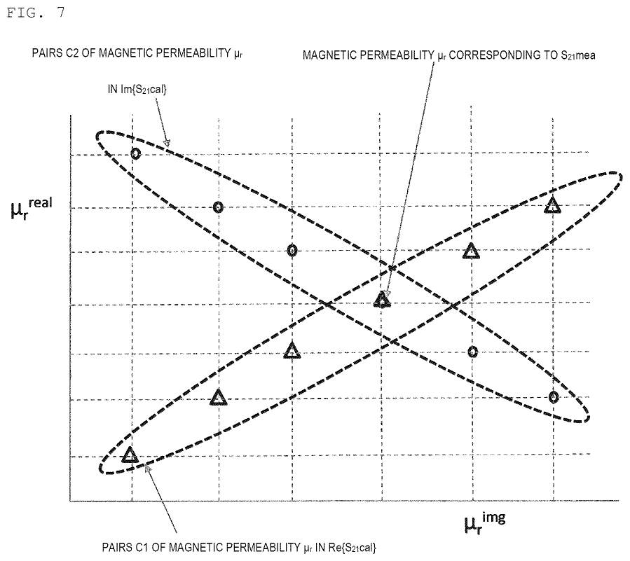

FIG. 7 shows the step of S106-3, in which the plurality of pairs C1 obtained in S106-1 and the plurality of pairs C2 obtained in S106-2 are plotted, and one pair whose real part and imaginary part of the relative magnetic permeability μᵣ match in the pairs is derived. Since the real parts u real and the imaginary parts μᵣ^{imag} of the relative magnetic permeability μᵣ are equal values in the real part Re{S₂₁mea} and the imaginary part Im{S₂₁mea} of the measured permeability coefficient S₂₁mea, this relative magnetic permeability μᵣ can be determined as the magnetic permeability of the measured permeability coefficient S₂₁mea. By obtaining the relation between the relative magnetic permeability μᵣ and the calculated permeability coefficient S₂₁cal by the analysis model of the electromagnetic field analysis software that is not affected by a demagnetizing field, and selecting, from the plurality of pairs of the magnetic permeability, a pair in which the real parts and the imaginary parts of the measured permeability coefficient S₂₁mea match, the magnetic permeability of the measured permeability coefficient S₂₁mea that is not affected by the demagnetizing field can be measured with high accuracy.

The optimization processing of S106 is executed for each frequency over a wide frequency range including a high frequency band exceeding 50 GHz, and the magnetic permeability μ is obtained for each frequency.

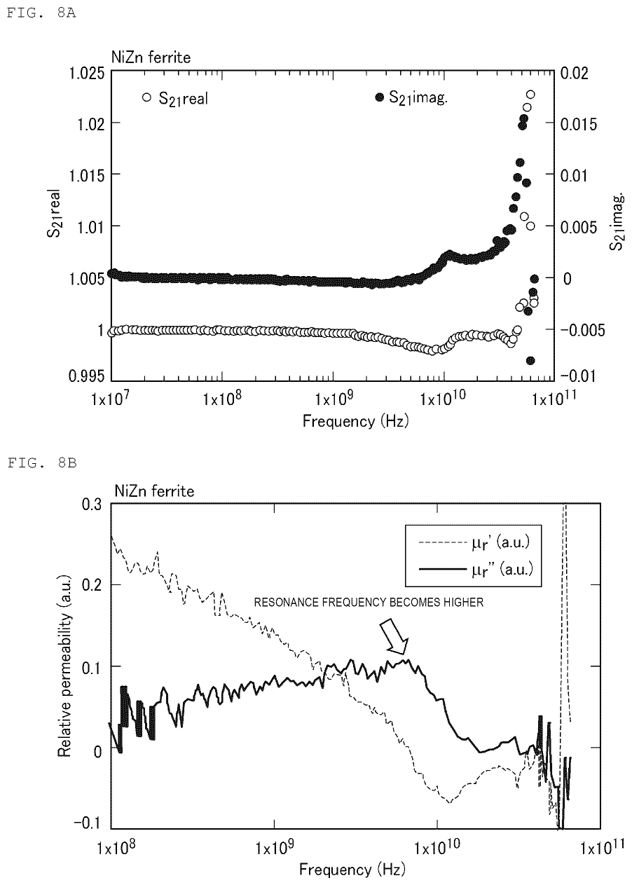

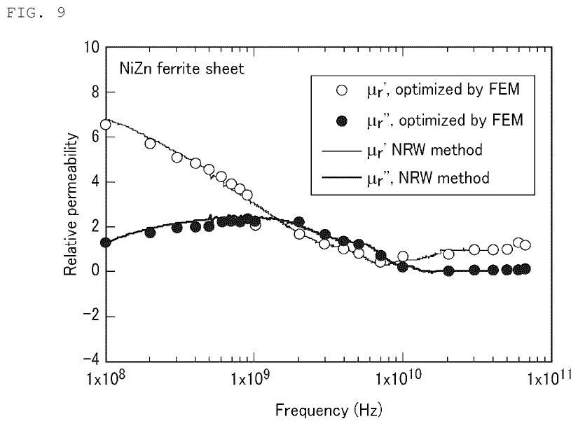

FIG. 8 and FIG. 9 are diagrams illustrating a first measurement result example of the magnetic permeability measuring method in the embodiment, and the magnetic material sample used in the first measurement result example is a NiZn ferrite sheet having a thickness of 100 μm, in which A of FIG. 8 is a graph showing values of the measured permeability coefficient S₂₁mea, B of FIG. 8 is a graph showing values of the relative magnetic permeability μᵣ obtained by a conventional method without considering the influence of the demagnetizing field, and FIG. 9 is a graph showing values of the relative magnetic permeability μᵣ obtained by the optimization processing by the magnetic permeability measuring method in the embodiment. In comparison with the values of the measured permeability coefficient S₂₁mea shown in A of FIG. 8, the values of the magnetic permeability μ shown in B of FIG. 8 are such that a resonant frequency in the imaginary part of the relative magnetic permeability μᵣ, in particular, becomes higher due to the influence of the demagnetizing field, resulting in an error in the magnetic permeability.

On the other hand, the magnetic permeability shown in FIG. 9 is obtained as a value that substantially matches the measured value by the Nicolson-Ross-Weir (NRW) method, which is a standard magnetic permeability measuring method, and it is confirmed that the magnetic permeability can be measured with high accuracy.

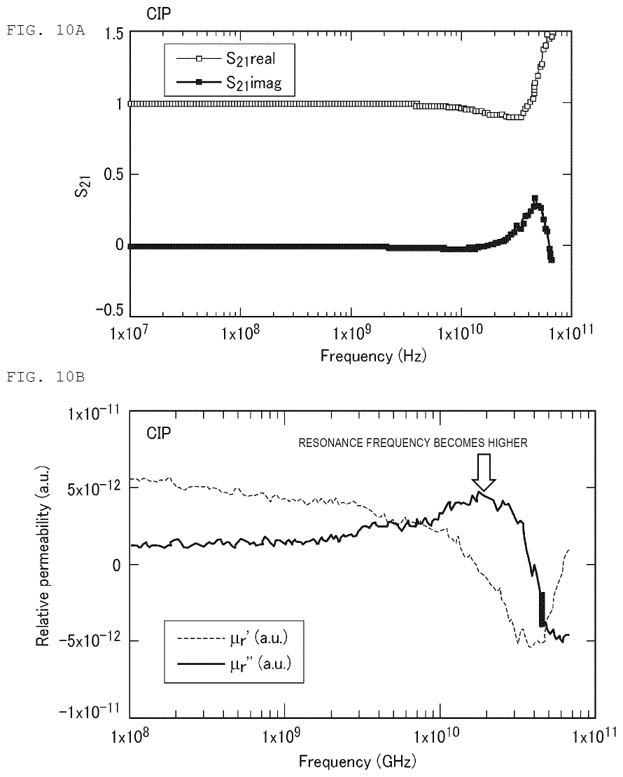

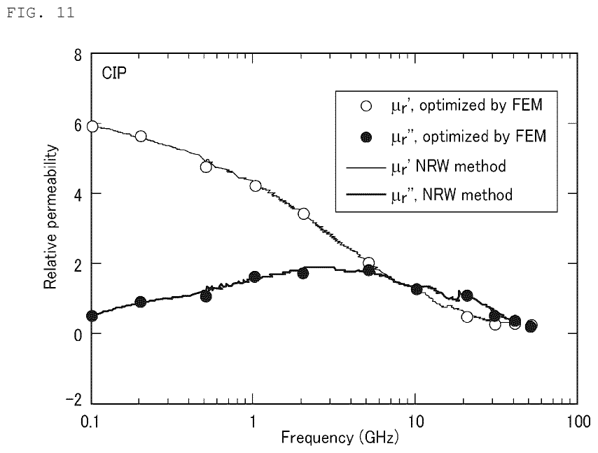

FIG. 10 and FIG. 11 are diagrams illustrating a second measurement result example of the magnetic permeability measuring method in the embodiment, and the magnetic material sample used in the second measurement result example is a CIP sheet (carbonyl iron powder sheet) having a thickness of 100 μm, in which A of FIG. 10 is a graph showing values of the measured permeability coefficient S₂₁mea, B of FIG. 10 is a graph showing values of the magnetic permeability μ obtained by a conventional method without considering the influence of the demagnetizing field, and FIG. 11 is a graph showing values of the magnetic permeability μ obtained by the optimization processing by the magnetic permeability measuring method in the embodiment. In comparison with the values of the measured permeability coefficient S₂₁mea shown in A of FIG. 10, the values of the relative magnetic permeability μᵣ shown in B of FIG. 10 are such that a resonant frequency in the imaginary part of the relative magnetic permeability μᵣ, in particular, becomes higher due to the influence of the demagnetizing field, resulting in an error in the magnetic permeability.

On the other hand, the magnetic permeability shown in FIG. 11 is obtained as a value that substantially matches the measured value by the Nicolson-Ross-Weir (NRW) method, which is a standard magnetic permeability measuring method, and it is confirmed that the magnetic permeability can be measured with high accuracy.

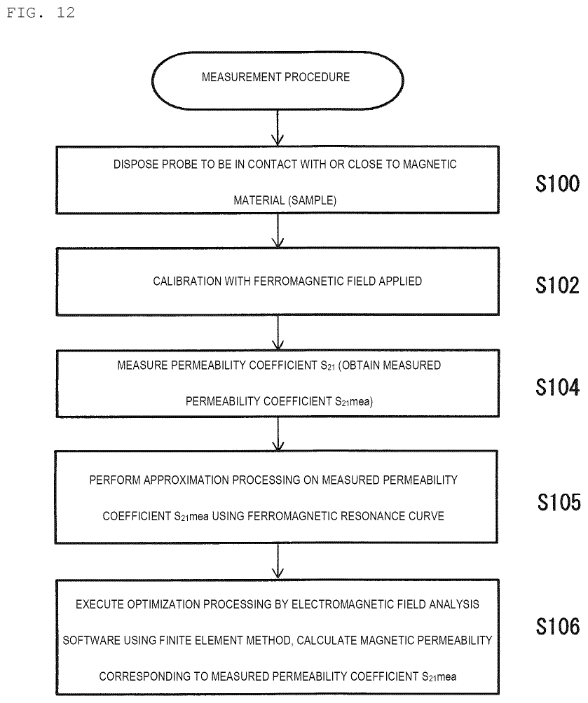

FIG. 12 is a flowchart showing another processing procedure of the magnetic permeability measuring method according to the embodiment of the invention. As compared with the processing procedure shown in FIG. 4, another processing procedure shown in FIG. 12 has additional processing (S105) of performing approximation processing using a ferromagnetic resonance curve on the measured permeability coefficient S₂₁mea measured in S104, and steps of S100, S102, S104, and S106 are the same as those in the processing procedure shown in FIG. 4. In S106, the magnetic permeability corresponding to the approximated measured permeability coefficient S₂₁mea is calculated.

In the processing of S105, the value of the measured permeability coefficient S₂₁mea is approximated by a ferromagnetic resonance curve represented by the following equation (3).

$${S}_{21} mea = {m}_{4} - {m}_{1}^{2} / {\{ {( {m}_{2}^{2 \cdot } {ω}^{2} )}^{2} + {m}_{3}^{2 \cdot } {ω}^{2} \}}^{1 / 2} \qquad ( 3 )$$

Here, ω represents a frequency, and m1, m2, m3, and m4 represent constants.

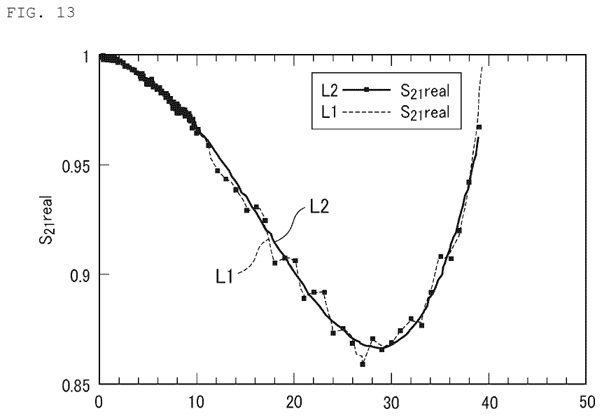

FIG. 13 is an example of a graph showing a part of the real part Re{S₂₁mea} of each of the measured permeability coefficient S₂₁mea before the approximation processing and the approximated measured permeability coefficient S₂₁mea. Actual measured values of the measured permeability coefficient S₂₁mea before the approximation processing indicated by a polygonal line L1 in FIG. 13 theoretically change along a predetermined curve according to the frequency as a whole, but in practice, each of the actual measured values of the measured permeability coefficient S₂₁mea varies and deviates from the approximation curve of the measured permeability coefficient S₂₁mea indicated by a solid line L2 in FIG. 13 due to the influence of noise and the like. Since there may be a possibility that an error occurs in the calculated magnetic permeability due to the variation and the deviation, it is possible to eliminate the variation and the deviation of the actual measured values and to calculate the magnetic permeability more accurately by obtaining the approximation curve L2 closest to each of the actual measured values of the measured permeability coefficients S₂₁mea by the above equation (3) and using the value on the approximation curve as the measured permeability coefficient S₂₁mea.

The above equation (3) is known as an equation representing a ferromagnetic resonance curve of a magnetic thin film (see, for example, Magnetic Engineering Course (5), Magnetic Thin Film Engineering, by Shuichi Iida, Maruzen, 1977, p 152-153, equation (4·29) and FIGS. 4·10), and it is suitable to adopt the equation (3) as an equation representing the approximation curve of the measured permeability coefficient S₂₁mea. In order to minimize the error between the measured value of the measured permeability coefficient S₂₁mea and the above equation (3), the approximation processing of determining the constants m1, m2, m3, and m4 of the above equation (3) is performed using a known least squares method, the approximation curve of the measured permeability coefficient S₂₁mea indicated by the solid line L2 in FIG. 13 is obtained, and the value on this curve is used as the measured permeability coefficient S₂₁mea to calculate the magnetic permeability.

The invention is not limited to the above-described embodiment, and it goes without saying that the invention includes design changes, including various modifications and alterations that could be conceived of by a person skilled in the art, which do not deviate from the gist of the invention.

### REFERENCE SIGNS LIST

1: magnetic material
3: coaxial cable
10: probe
11: strip conductor
12: dielectric (flexible substrate)
14: ground conductor
15: connector
20: network analyzer (signal measuring device)
30: arithmetic processing device
40: electromagnet

1. A magnetic permeability measuring method for measuring a magnetic permeability of a magnetic material, the magnetic permeability measuring method comprising:
a step of measuring a measured permeability coefficient of the magnetic material using a measuring probe;
a step of setting an analysis model corresponding to a measurement condition in the measuring step, and calculating, using finite element analysis, a calculated permeability coefficient of the magnetic material in the analysis model and the magnetic permeability of the magnetic material corresponding to the calculated permeability coefficient;
a step of acquiring a first set comprising a plurality of pairs of real parts and imaginary parts of the magnetic permeability corresponding to a real part of the calculated permeability coefficient that matches a real part of the measured permeability coefficient;
a step of acquiring a second set comprising a plurality of pairs of real parts and imaginary parts of the magnetic permeability corresponding to an imaginary part of the calculated permeability coefficient that matches an imaginary part of the measured permeability coefficient; and
a step of determining the magnetic permeability whose real part and imaginary part match in the first set and the second set.

2. The magnetic permeability measuring method according to claim 1, wherein
the measuring probe is provided with a signal transmission line comprising a belt-like strip conductor formed on a front face of a dielectric substrate and a ground conductor formed on the front face or a back face of the dielectric substrate, and
the magnetic material is brought into contact with or close to the signal transmission line, and the measured permeability coefficient of the magnetic material is measured by a signal measuring device electrically connected to the signal transmission line.

3. The magnetic permeability measuring method according to claim 2, wherein
the signal transmission line is a microstrip line.

4. The magnetic permeability measuring method according to claim 1, wherein
approximation processing of approximating values of the measured permeability coefficient measured over a predetermined frequency range to a predetermined approximation curve is performed, and a value on the approximation curve is applied as the measured permeability coefficient.

5. The magnetic permeability measuring method according to claim 4, wherein
the approximation curve is represented by
$${measured permeability coefficient = {m}_{4} - {m}_{1}^{2} / {\{ ( {m}_{2}^{2 \cdot } {ω}^{2} \}}^{2} + {m}_{3}^{2 \cdot } {ω}^{2} \}}^{1 / 2} ,$$
where ω represents a frequency, and m1, m2, m3, and m4 represents constants.

6. A measuring device for measuring a magnetic permeability of a magnetic material, the magnetic permeability measuring device comprising:
a measuring probe provided with a signal transmission line and capable of being set such that the magnetic material is brought close to or into contact with the signal transmission line;
a magnetic field application unit configured to apply a magnetic field to the magnetic material;
a signal measuring device configured to measure a measured permeability coefficient of the magnetic material; and
an arithmetic processing device configured to calculate the magnetic permeability of the magnetic material based on the measured permeability coefficient by arithmetic processing, wherein
the arithmetic processing device is configured to
set an analysis model corresponding to a measurement condition for the measured permeability coefficient, and calculate, using finite element analysis, a calculated permeability coefficient of the magnetic material in the analysis model and the magnetic permeability of the magnetic material corresponding to the calculated permeability coefficient,
acquire a first set comprising a plurality of pairs of real parts and imaginary parts of the magnetic permeability corresponding to a real part of the calculated permeability coefficient that matches a real part of the measured permeability coefficient,
acquire a second set comprising a plurality of pairs of real parts and imaginary parts of the magnetic permeability corresponding to an imaginary part of the calculated permeability coefficient that matches an imaginary part of the measured permeability coefficient, and
determine the magnetic permeability whose real part and imaginary part match in the first set and the second set.
